(19) United States
(12) Patent Application Publication
(10) Pub. No.: US 2026/0096392 A1
(43) Pub. Date: Apr. 2, 2026

(54) SUBSTRATE TRANSFER APPARATUS

(71) Applicant: SAMSUNG DISPLAY CO., LTD., Yongin-si (KR)

(72) Inventors: You Jong LEE, Yongin-si (KR); Seo Kyu KIM, Yongin-si (KR); Jong Hwan JUNG, Yongin-si (KR); Seung Ho CHOI, Yongin-si (KR); Myung Soo HUH, Yongin-si (KR)

(21) Appl. No.: 19/235,700

(22) Filed: Jun. 12, 2025

(30) Foreign Application Priority Data
Oct. 2, 2024 (KR) 10-2024-0133836

(51) Int. Cl. H01L 21/677

(52) U.S. Cl. CPC H10P 72/3204; H10P 72/3202

(57) ABSTRACT

A substrate transfer apparatus including: a chamber; a carrier with a first concave portion facing the chamber and extending in a first direction, positioned vertically in a second direction intersecting the first direction while securing a substrate, and capable of being introduced into or removed from the chamber in the first direction; roller components in the chamber, positioned in the first concave portion; linear movable components in the chamber; first magnet components in the carrier, facing the linear movable components in the second direction; second magnet components in the chamber, opposite the first magnet components in the second direction; and third magnet components in the carrier, facing the second magnet components, wherein the carrier is transferred while maintaining a gap between the linear movable components and first magnet components, facilitated by a magnetic force between the second and third magnet components.

### CROSS-REFERENCE TO RELATED APPLICATION

This application claims priority under 35 U.S.C. § 119 to Korean Patent Application No. 10-2024-0133836, filed on Oct. 2, 2024, in the Korea Intellectual Property Office, the disclosure of which is incorporated by reference herein in its entirety.

### 1. TECHNICAL FIELD

Various embodiments of this disclosure relate to a substrate transfer apparatus.

### 2. DESCRIPTION OF THE RELATED ART

The importance of display devices continues to grow with advancements in multimedia technology. To accommodate this demand, various types of display devices, including organic light emitting display devices, and liquid crystal display devices, are widely utilized.

Display devices typically consist of light-emitting elements that generate light and circuit elements that supply the necessary electrical signals. As display technology has advanced, the materials used for these components have diversified. The fabrication of display devices involves depositing multiple ultra-thin material layers onto a substrate. This deposition process is carried out as the substrate is sequentially transferred through multiple processing chambers to ensure precise layer formation.

### SUMMARY

This disclosure is directed to a substrate transfer apparatus, capable of preventing or reducing friction occurring between a carrier and a driving system during a process of transferring the substrate.

An embodiment of the disclosure provides a substrate transfer apparatus including: a chamber; a carrier including a first concave portion facing the chamber and extending in a first direction, wherein the carrier is configured to be positioned vertically in a second direction intersecting with the first direction while securing a substrate thereon, and introduced into or removed from the chamber in the first direction; a plurality of roller components installed in the chamber and positioned in the first concave portion; a plurality of linear movable components installed in the chamber and configured to generate a driving force for transferring the carrier in the first direction; a plurality of first magnet components installed in the carrier and positioned to face the plurality of linear movable components in the second direction; a plurality of second magnet components installed in the chamber on a side opposite to the plurality of first magnet components in the second direction; and a plurality of third magnet components installed in the carrier and positioned to face the plurality of second magnet components, wherein the carrier is transferred while maintaining a gap between the plurality of linear movable components and the plurality of first magnet components, with the transfer being facilitated by a magnetic force acting between the plurality of second magnet components and the plurality of third magnet components.

The first direction is a horizontal direction, and the second direction is a vertical direction.

The chamber includes a first chamber portion, and a second chamber portion positioned on a side opposite to the first chamber portion with respect to the second direction, and the carrier includes a first carrier portion adjacent to the first chamber portion, and a second carrier portion adjacent to the second chamber portion.

The plurality of roller components are arranged in the first chamber portion in the first direction, and the first concave portion is formed in the first carrier portion in the first direction.

The plurality of linear movable components are installed in the first chamber portion, and the first magnet components are installed in the first carrier portion.

The plurality of second magnet components are installed in the second chamber portion, and the third magnet components are installed in the second carrier portion.

The chamber includes a first protrusion protruding from the second chamber portion in the second direction, and the plurality of second magnet components are installed in the first protrusion.

A first attractive force acts between the plurality of linear movable components and the first magnet components, and a second attractive force acts between the plurality of second magnet components and the plurality of third magnet components.

The first concave portion includes: a first roller guide disposed adjacent to a first side of the chamber; and a second roller guide disposed adjacent to a second side of the chamber.

The first roller guide and the second roller guide are integrally formed with the carrier.

The first roller guide and the second roller guide include a material different from a material of the carrier.

When the second attractive force is greater than a sum of the first attractive force, a weight of the carrier, and a weight of the substrate secured to the carrier, the carrier moves toward the plurality of second magnet components, and the plurality of roller components come into contact with the first roller guide.

When the second attractive force is less than a sum of the first attractive force, a weight of the carrier, and a weight of the substrate secured to the carrier, the carrier moves toward the plurality of first magnet components, and the plurality of roller components come into contact with the second roller guide.

The carrier further includes a second concave portion formed parallel to the first concave portion along the second direction, and the chamber includes a second protrusion protruding toward the second concave portion.

The substrate transfer apparatus further includes: a plurality of fourth magnet components installed in the second protrusion; and a plurality of fifth magnet components installed in the carrier and positioned to face the plurality of fourth magnet components, wherein the carrier moves toward the plurality of second magnet components due to a third attractive force acting between the plurality of fourth magnet components and the plurality of fifth magnet components.

When a sum of the second attractive force and the third attractive force is greater than a sum of the first attractive force, a weight of the carrier, and a weight of the substrate secured to the carrier, the carrier moves toward the plurality of second magnet components, and the plurality of roller components come into contact with the first roller guide.

An embodiment of the disclosure provides a substrate transfer apparatus including: a chamber; a carrier configured to be placed in a first direction while securing a substrate thereon, and introduced into or removed from the chamber; a plurality of linear movable components installed in a first chamber portion of the chamber, and configured to generate a driving force for transferring the carrier in a second direction intersecting with the first direction; a plurality of first magnet components installed in a first carrier portion of the carrier and positioned to face the plurality of linear movable components in the first direction; a plurality of second magnet components installed in the first chamber portion and inclined at a first angle with respect to the first direction; a plurality of third magnet components installed in the first carrier portion and positioned to face the plurality of second magnet components while being inclined at a second angle with respect to the first direction; a plurality of fourth magnet components installed in a second chamber portion positioned on a side opposite to the first chamber portion with respect to the first direction; and a plurality of fifth magnet components installed in a second carrier portion adjacent to the second chamber portion and positioned to face the plurality of fourth magnet components, wherein the carrier is transferred while maintaining a gap between the plurality of linear movable components and the plurality of first magnet components are spaced apart, with the transfer being facilitated by a magnetic force acting between the plurality of second magnet components and the plurality of third magnet components.

The plurality of second magnet components include a plurality of 2_1-th magnet components and a plurality of 2_2-th magnet components, which are symmetrically arranged with respect to the first direction, the plurality of third magnet components include a plurality of 3_1-th magnet components and a plurality of 3_2-th magnet components, which are symmetrically arranged with respect to the first direction, the plurality of 2_1-th magnet components and the plurality of 3_1-th magnet components face each other, the plurality of 2_2-th magnet components and the plurality of 3_2-th magnet components face each other, a first repulsive force acts between the plurality of 2_1-th magnet components and the plurality of 3_1-th magnet components, and a second repulsive force acts between the plurality of 2_2-th magnet components and the plurality of 3_2-th magnet components.

The first carrier portion includes: a carrier end portion where the plurality of first magnet components are installed; and a carrier slant portion where the plurality of third magnet components are installed, wherein the first chamber portion includes: a chamber transfer space positioned at the carrier end portion; and a chamber slant portion facing the carrier slant portion, with a chamber hole formed in the chamber slant portion to expose the chamber transfer space, wherein a chamber slant surface of the chamber slant portion and a carrier slant surface of the carrier slant portion are parallel to each other, wherein the plurality of second magnet components are installed in the chamber slant surface, and wherein the plurality of third magnet components are installed in the carrier slant surface.

A first attractive force acts between the plurality of linear movable components and the plurality of first magnet components, and a repulsive force acts between the plurality of second magnet components and the plurality of third magnet components, and a second attractive force acts between the plurality of fourth magnet components and the plurality of fifth magnet components, and a sum of the first attractive force, a weight of the carrier, and a weight of the substrate secured to the carrier is substantially equal to a sum of the second attractive force and the repulsive force.

An embodiment of the disclosure provides a substrate transfer apparatus including: a chamber; a carrier configured to secure a substrate thereon and be movable along a transfer path within the chamber; a support structure within the chamber configured to guide the movement of the carrier along the transfer path; a drive mechanism configured to apply a transfer force to the carrier to facilitate its movement along the transfer path; a first magnetic component associated with the carrier; and a second magnetic component associated with the chamber, wherein the first and second magnetic components generate a magnetic interaction that at least partially supports the carrier to reduce mechanical contact with the support structure during movement.

### BRIEF DESCRIPTION OF THE DRAWINGS

FIG. 1 is a view illustrating an embodiment of a substrate transfer apparatus.

FIG. 2 is a view illustrating an enlargement of portion A of FIG. 1.

FIG. 3 is a view illustrating an enlargement of portion B of FIG. 1.

FIG. 4 is a front view illustrating the substrate transfer apparatus illustrated in FIG. 1.

FIG. 5 is a view illustrating a first operation example of the substrate transfer apparatus illustrated in FIG. 1.

FIG. 6 is a view illustrating a second operation example of the substrate transfer apparatus illustrated in FIG. 1.

FIG. 7 is a view illustrating another embodiment of the substrate transfer apparatus illustrated in FIG. 6.

FIG. 8 is a view illustrating another embodiment of the substrate transfer apparatus illustrated in FIG. 1.

FIG. 9 is a view illustrating an enlargement of portion C of FIG. 8.

FIG. 10 is a view illustrating an enlargement of portion D of FIG. 8.

FIG. 11 is a front view illustrating the substrate transfer apparatus illustrated in FIG. 8.

### DETAILED DESCRIPTION OF THE EMBODIMENTS

Hereinafter, embodiments of this disclosure will be described in detail with reference to the attached drawings. In the following description, only the components necessary for understanding the operation of this disclosure will be described, while other details are omitted to maintain clarity. Accordingly, this disclosure is not limited to the embodiments set forth herein and may be implemented in various other forms. Rather, these embodiments are provided so that this disclosure will be thorough and complete, and will fully convey the technical spirit of the disclosure to those skilled in the art.

It will be understood that when an element is referred to as being “coupled” or “connected” to another element, an element can be directly coupled or connected to the other element or intervening elements may be present therebetween. The terminology used herein is for the purpose of describing particular embodiments only and is not intended to be limiting. For example, the singular forms are intended to include the plural forms as well, unless the context clearly indicates otherwise. In addition, when an element is referred to as “comprising” or “including” a component, it does not preclude another component but may further include the other component unless the context clearly indicates otherwise. The phrases “at least one of X, Y, and Z” and “at least one selected from the group consisting of X, Y, and Z” may be construed as X only, Y only, Z only, or any combination of two or more of X, Y, and Z (for instance, XYZ, XYY, YZ, and ZZ). As used herein, the term “and/or” can include any and all combinations of one or more of the listed items.

Here, the terms “first,” “second,” etc., are used to differentiate various elements and do not imply any particular order or hierarchy. Thus, a first element discussed below could be termed a second element.

Spatially relative terms, such as “beneath,” “below,” “under,” “lower,” “above,” “upper,” “over,” “higher,” “side” (e.g., “sidewall”), and the like, may be used herein for descriptive purposes to indicate the relationship between elements or features, as illustrated in the drawings. Spatially relative descriptors are intended to encompass different orientations of an apparatus in use, operation, and/or manufacture in addition to the orientation depicted in the drawings. For example, if the device in the drawings is turned upside down, elements described as “below” or “beneath” other elements or features would then be oriented “above” the other elements or features. Thus, the term “below” can encompass both an orientation of above and below. Furthermore, the device may be oriented differently (e.g., rotated 90 degrees or positioned at another angle). Accordingly, the spatially relative descriptors used herein should be interpreted based on the device's actual orientation in a given context.

Various embodiments will be described hereinafter with reference to diagrams illustrating idealized embodiments. As such, variations from the shapes of the illustrations as a result, for example, of manufacturing techniques and/or tolerances, are to be expected. Therefore, the embodiments disclosed herein should not be construed as limited to the particular illustrated shapes of regions, but are to include deviations in shapes that result from, for instance, manufacturing. As such, the shapes illustrated in the drawings may not illustrate the actual shapes of regions of a device, and, as such, are not intended to be limiting.

This disclosure relates to a substrate transfer apparatus designed to minimize friction and contamination during the transfer of substrates, such as those used in display device manufacturing. The system incorporates magnetic levitation, where magnets installed in both the carrier and the chamber create an attractive force that allows the carrier to move without direct contact with the chamber walls. Additionally, linear movable components generate the driving force for precise positioning and movement of the carrier. By reducing physical contact, the disclosure significantly decreases the generation of foreign particles, which can otherwise lead to defects in display panels. This enhances both the cleanliness of the process and the durability of the transfer system.

Furthermore, the apparatus includes a roller-guided system within a concave portion of the carrier, ensuring stable movement even when the magnetic levitation effect is interrupted. The system dynamically adjusts the balance of attractive and repulsive magnetic forces to maintain the carrier's position, preventing unintended vibrations or misalignment. By leveraging magnetic levitation and controlled movement, the disclosure improves the efficiency and reliability of substrate transport while preventing wear and tear on mechanical components. This innovation is particularly valuable in OLED and LCD panel manufacturing, where even minute contaminants can compromise product quality.

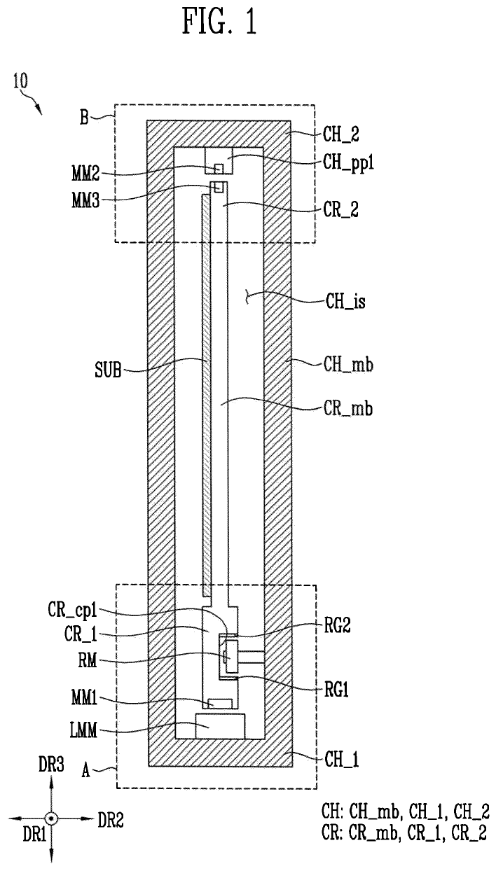

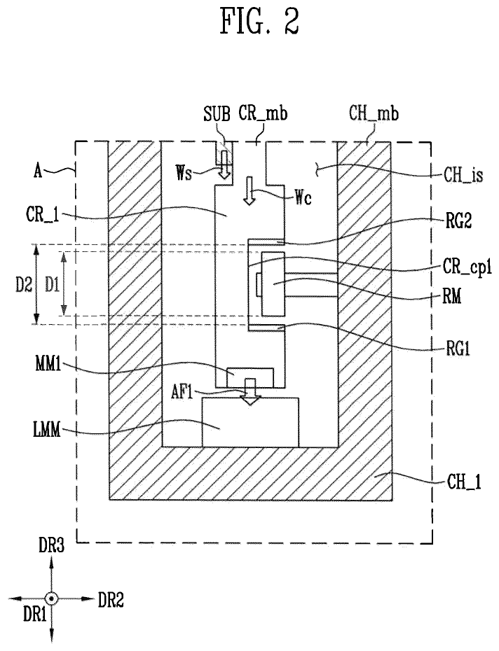

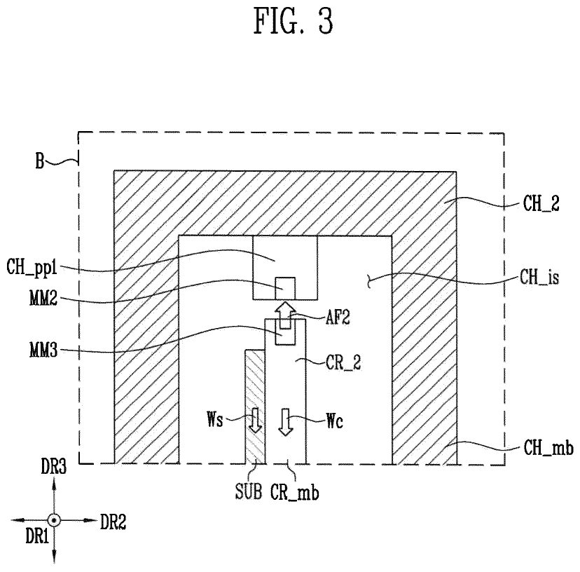

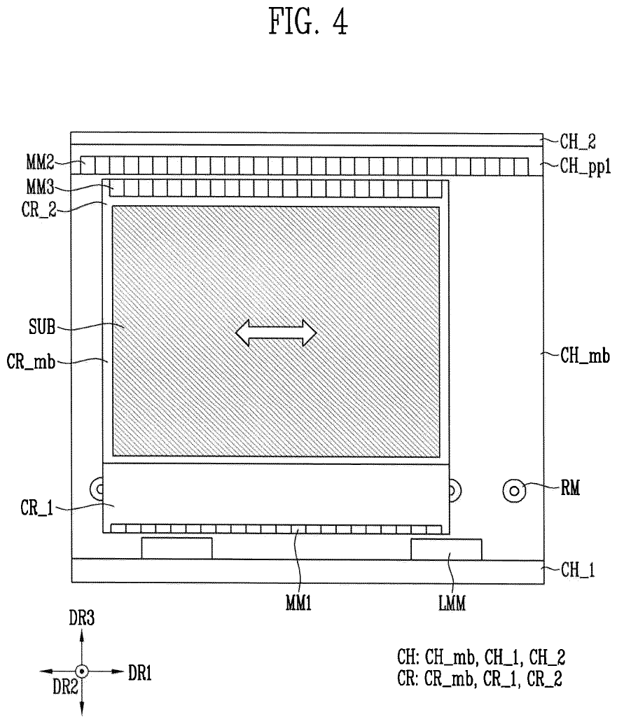

FIG. 1 is a view illustrating an embodiment of a substrate transfer apparatus 10. FIG. 2 is a view illustrating an enlargement of portion A of FIG. 1. FIG. 3 is a view illustrating an enlargement of portion B of FIG. 1. FIG. 4 is a front view illustrating the substrate transfer apparatus 10 illustrated in FIG. 1.

Referring to FIGS. 1 to 4, the substrate transfer apparatus 10 may include a chamber CH, a carrier CR, a plurality of roller components RM, a plurality of linear movable components LMM, a plurality of first magnet components MM1, a plurality of second magnet components MM2, and a plurality of third magnet components MM3.

The chamber CH may provide an enclosed space for performing a deposition process, shielding it from external conditions. Within the chamber CH, a material that forms a light emitting element or circuit element may be deposited on the substrate SUB. Although not illustrated in the drawings, the chamber CH may include a passage for loading and unloading the substrate SUB, and a door for opening and closing the passage, both provided on a side surface of the chamber CH.

The chamber CH may include a main chamber body CH_mb, a first chamber portion CH_1, and a second chamber portion CH_2.

The main chamber body CH_mb may be disposed to overlap the substrate SUB within an internal space CH_is of the chamber CH in each of first and second directions DR1 and DR2. Here, the first direction DR1 may refer to a direction in which the substrate SUB is transferred. The second direction DR2 may refer to a thickness direction of the substrate SUB.

The first chamber portion CH_1 may be a portion of the chamber CH located on a first side of the chamber CH in a third direction DR3, which intersects with the first and second directions DR1 and DR2. The roller components RM and the linear movable components LMM may be installed in the first chamber portion CH_1. Details of the roller components RM and the linear movable components LMM will be described below.

The second chamber portion CH_2 may be another portion of the chamber CH disposed on a second side of the chamber CH in the third direction DR3. The second magnet components MM2 may be installed in the second chamber portion CH_2. The second chamber portion CH_2 may include a first protrusion CH_pp1 in which the second magnet components MM2 are disposed. Details of the second magnet components MM2 and the first protrusion CH_pp1 will be described below.

The carrier CR may be configured to transfer the substrate SUB in the first direction DR1. The carrier CR may be positioned vertically in the third direction DR3 while securing the substrate SUB, enabling its introduction into or removal from the chamber CH. The substrate SUB may be secured on the carrier CR by various methods. For example, the carrier CR may use a device such as a clamper or an electrostatic chuck to secure the substrate SUB on one surface of the carrier CR.

The carrier CR may include a main carrier body CR_MB, a first carrier portion CR_1, a second carrier portion CR_2, and a first concave portion CR_cp1.

The main carrier body CR_mb may overlap the main chamber body CH_mb in each of the first and second directions DR1 and DR2. Since the main chamber body CH_mb may overlap the substrate SUB in each of the first and second directions DR1 and DR2, the main carrier body CR_mb may also overlap the substrate SUB in each of the first and second directions DR1 and DR2.

The first carrier portion CR_1 may be a portion of the carrier CR disposed on a first side of the carrier CR in the third direction DR3. The first carrier portion CR_1 may be adjacent to the first chamber portion CH_1. In other words, the first chamber portion CH_1 and the first carrier portion CR_1 may be adjacent to each other in one area of the substrate transfer apparatus 10.

The first magnet components MM1 may be installed in the first carrier portion CR_1. The first concave portion CR_cp1 that receives the roller components RM may be formed in the first carrier portion CR_1. Here, the first concave portion CR_cp1 receiving the roller components RM means that the roller components RM are positioned within the empty space of the carrier CR formed by the first concave portion CR_cp1. However, they are not completely fitted into it, leaving a certain margin space (degree of freedom) that allows the roller components RM to move in the third direction DR3.

The second carrier portion CR_2 may refer to another portion of the carrier CR disposed on a second side of the carrier CR in the third direction DR3. The third magnet components MM3 may be installed in the second carrier portion CR_2. Details of the third magnet components MM3 will be described below.

The first concave portion CR_cp1 is formed in the first carrier portion CR_1, and may provide an empty space to receive the roller components RM therein. In the embodiments, the first concave portion CR_cp1 is an area that is recessed from one surface of the first carrier portion CR_1 facing the first chamber portion CH_1 in a direction away from the first chamber portion CH_1 by a certain depth.

The first concave portion CR_cp1 may include a first roller guide RG1 that is relatively adjacent to the first chamber portion CH_1, and a second roller guide RG2 that is relatively adjacent to the second chamber portion CH_2.

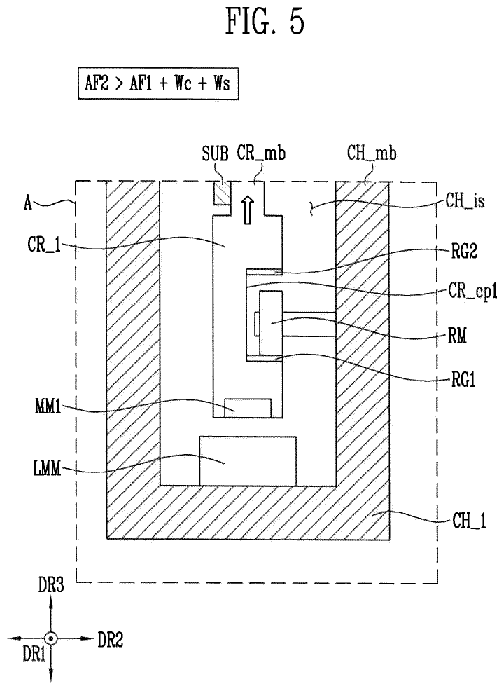

The first and second roller guide RG1 and RG2 may be integrally formed with the carrier CR. In the embodiments, each of the first and second roller guides RG1 and RG2 may be an inner surface of the carrier CR where the first concave portion CR_cp1 is formed. Each of the first and second roller guides RG1 and RG2 may correspond to a partial area of the carrier CR that can contact the roller components RM when the carrier CR moves in the second direction DR2. For example, when the carrier CR moves toward the first chamber portion CH_1, the roller components RM may contact the second roller guide RG2. In addition, when the carrier CR moves toward the second chamber portion CH_2, the roller components RM may contact the first roller guide RG1. The foregoing structure will be described in detail with reference to FIGS. 5 to 7.

The roller components RM may be installed in the chamber CH and disposed in the first concave portion CR_cp1. For example, each of the roller components RM may be installed in the first chamber portion CH_1, and may be spaced apart from each other in the first direction DR1 that is the direction in which the substrate SUB is transferred. In the embodiments, each of the roller components RM may be formed of a rotating shaft and a roller. The rotating shaft may be installed in the first chamber portion CH_1, and may extend in a direction toward the first concave portion CR_cp1. The roller may be rotatably connected to a portion of the rotating shaft that overlaps the first concave portion CR_cp1 in the third direction DR3.

Referring to FIG. 2, each of the roller components RM may have a length less than that of the first concave portion CR_cp1 (D1<D2) in the third direction DR3, which is the direction in which a weight Wc of the carrier CR and/or a weight Ws of the substrate SUB is applied to the roller components RM. In the embodiments, each of the roller components RM received in the first concave portion CR_cp1 may have a length of D1 in the third direction DR3, and the first concave portion CR_cp1 may have a length of D2, where D2 is greater than D. With this structure, each of the roller components RM may have a degree of freedom in the third direction DR3, determined by the difference between the width D1 of the roller component RM and the width D2 of the first concave portion CR_cp1.

The linear movable components LMM may be installed in the chamber CH to provide a driving force for moving the carrier CR in the first direction DR1. For example, the linear movable components LMM may be installed in the first chamber portion CH_1 and spaced apart from each other in the first direction DR1, which is the direction in which the substrate SUB is transferred. The linear components LMM may also be disposed to face the first carrier portion CR_1 in the third direction DR3.

The linear movable components LMM may use a magnetic force to transfer the carrier CR in the first direction DR1. For example, each of the linear movable components LMM may include an armature coil. The linear movable components LMM may face the first magnet components MM1 to be described below in the third direction, and may generate a driving force for transferring the carrier CR in the first direction DR1 by applying a current to each of the linear movable components LMM.

The first magnet components MM1 may be configured as permanent magnets with specific magnetic forces and may be installed in the carrier CR to face the linear movable components LMM in the third direction DR3. In the embodiments, the first magnet components MM1 may be installed on a surface positioned at the end of the first carrier portion CR_1, adjacent to the first chamber portion CH_1 in the third direction DR3. However, their placement is not limited to this configuration. For example, the first magnet components MM1 may be embedded in the end of the first carrier portion CR_1.

Referring to FIG. 2, a first attractive force AF1 may act between the linear movable components LMM and the first magnet components MM1. Here, the first attractive force AF1 may refer to an electrostatic force that causes the linear movable components LMM and the first magnet components MM1 to attract each other in the third direction DR3. In the embodiments, the linear movable components LMM are installed in the fixed first chamber portion CH_1, while the first magnet components MM1 are installed in the carrier CR, which is movable in the third direction DR3. Consequently, the carrier CR may experience a force that draws the first carrier portion CR_1 toward the first chamber portion CH_1 due to the first attractive force AF1.

The second magnet components MM2 may be configured as permanent magnets with specific magnetic forces, similar to the first magnet components MM1. The second magnet components MM2 may be installed in a portion of the chamber CH on a side opposite to the first magnet components MM1 in the third direction DR3. In the embodiments, the second magnet components MM2 may be installed at the end of the first protrusion CH_pp1, which extends from the second chamber portion CH_2 toward the second carrier portion CR_2 in the third direction DR3, though their placement is not limited to this configuration. For example, the second magnet components MM2 may be embedded in the end of the first protrusion CH_pp1.

In some embodiments, the first protrusion CH_pp1 may be omitted. In other embodiments, the second magnet components MM2 may be installed on one surface of the second chamber portion CH_2 that is adjacent to the second carrier portion CR_2, but their placement is limited to this configuration. For example, the second magnet components MM2 may be embedded in one surface of the second chamber portion CH_2 that faces the second carrier portion CR_2 in the third direction DR3.

The third magnet components MM3 may be configured as permanent magnets with specific magnetic forces, similar to the first and second magnet components MM1 and MM2. The third magnet components MM3 may be installed in the carrier CR to face the second magnet components MM2 in the third direction DR3. In the embodiments, the third magnet components MM3 may be installed in a surface positioned at the end of the second carrier portion CR_2 that is adjacent to the second chamber portion CH_2 in the third direction DR3, but their placement is not limited to this configuration. For example, the third magnet components MM3 may be embedded in the end of the second carrier portion CR_2.

As illustrated in FIG. 3, a second attractive force AF2 may act between the second magnet components MM2 and the third magnet components MM3. Here, the second attractive force AF2 may refer to the magnetic force that causes the second magnet components MM2 and the third magnet components MM3 to attract each other in the third direction DR3. In the embodiments, the second magnet components MM2 are installed in the fixed chamber CH, while the third magnet components MM3 are installed in the carrier CR, which has a certain degree of freedom in the third direction DR3. Consequently, the carrier CR may experience a force that draws the second carrier portion CR_2 toward the second chamber portion CH_2 due to the second attractive force AF2.

Referring collectively to FIGS. 2 and 3, the second attractive force AF2 may act in a direction opposite to the force drawing the carrier CR toward the first chamber portion CH_1, which results from the first attractive force AF1, the weight Ws of the substrate SUB, or the weight Wc of the carrier CR. In the embodiments, when the second attractive force AF2 balances the combined effect of the first attractive force AF1, the weight Ws of the substrate SUB, and the weight Wc of the carrier CR, the carrier CR may be spaced apart from the linear movable components LMM, as shown in FIG. 2. In this state, the roller components RM do not contact the first and second roller guides RG1 and RG2 within the first concave portion CR_cp1, achieving a magnetic levitation state. In other words, the carrier CR may be transferred while being suspended, with the linear movable components LMM and the first magnet components MM1 remaining spaced apart due to the magnetic force acting between the second magnet components MM2 and the third magnet components MM3.

If the second attractive force AF2 acting between the second and third magnet components MM2 and MM3 is not utilized, the carrier CR will inevitably come into contact with the driving system installed in the chamber CH during movement. In this case, fine particles generated by friction between the carrier CR and the driving system of the chamber CH may infiltrate the substrate SUB. Multiple layers of thin films that form the light emitting element and the circuit element of the display device are deposited on the substrate SUB, and if foreign particles are introduced into the thin films, defects in the display device may be caused.

However, in the substrate transfer apparatus 10 according to the above-described embodiments, the second attractive force AF2 may balance the combined effect of the first attractive force AF1, the weight Ws of the substrate SUB, and the weight Wc of the carrier CR. Accordingly, the carrier CR can be transferred without contact with other components, achieving a magnetic levitation state. This prevents friction between the carrier CR and the driving system of the chamber CH during substrate SUB transfer, effectively eliminating the generation of foreign particles and reducing defects in the display device.

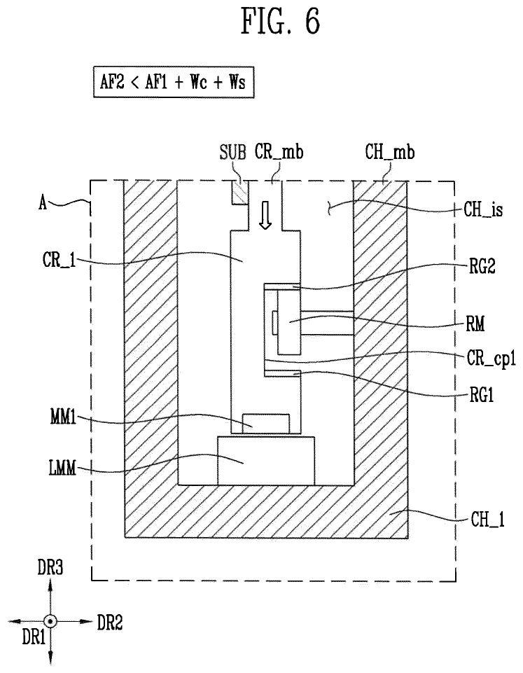

Hereinafter, a relationship between the first and second attractive forces AF1 and AF2, the weight Ws of the substrate SUB, and the weight Wc of the carrier CR, and the resulting driving orientation of the carrier CR will be described in detail with reference to FIGS. 5 and 6.

FIG. 5 is a view illustrating a first operation example of the substrate transfer apparatus 10 illustrated in FIG. 1. FIG. 6 is a view illustrating a second operation example of the substrate transfer apparatus 10 illustrated in FIG. 1.

FIG. 5 illustrates movement of the carrier CR when the second attractive force AF2 is greater than the sum of the first attractive force AF1, the weight Wc of the carrier CR, and the weight Ws of the substrate SUB fixed to the carrier CR. The aforementioned case may frequently occur during the operation of the substrate transfer apparatus 10 and may arise when the second attractive force AF2 deviates from a balanced state with the sum of the first attractive force AF1, the weight Wc of the carrier CR, and the weight Ws of the substrate SUB secured to the carrier CR.

As described above, the second attractive force AF2 refers to the force pulling the carrier CR toward the second chamber portion CH_2 in which the second magnet components MM2 are installed. Therefore, when the second attractive force AF2 exceeds the sum of the first attractive force AF1, the weight Wc of the carrier CR, and the weight Ws of the substrate SUB secured to the carrier CR, the carrier CR may be drawn toward the second chamber portion CH_2, where the second magnet components MM2 are installed. As a results, if the carrier CR moves in the direction toward the second chamber portion CH_2, the roller components RM may gradually approach the first roller guide RG1 within the first concave portion CR_cp1, eventually making contact with the first roller guide RG1.

The force with which the roller components RM contact the first roller guide RG1 is determined by subtracting the sum of the first attractive force AF1, the weight Ws of the substrate SUB, and the weight Wc of the carrier CR from the second attractive force AF2. Since the second attractive force AF2 is a considerable magnetic force, the resulting contact force is much smaller than a frictional force that would otherwise be generated between the roller components RM and the first roller guide RG1 (i.e., the chamber CH) if the first roller guide RG1 were to fully support the weight Ws of the substrate SUB and the weight Wc of the carrier CR without the assistance of the second attractive force AF2. This means that, in the substrate transfer apparatus 10 according to the embodiments, friction between the carrier CR and the roller components RM is significantly reduced compared to a system that does not utilize the first to third magnet components MM1 to MM3. As a result, even if foreign particles are generated during the transfer of the substrate SUB, the overall amount of such particles can be significantly minimized.

In addition, since the first concave portion CR_cp1 is formed on the surface of the carrier CR opposite to the surface of the carrier CR where the substrate SUB is fixed, any foreign particles generated due to friction between the carrier Cr and the roller components RM are unlikely to significantly escape from the first concave portion CR_cp1 and its surrounding area. This effectively prevents the introduction of foreign particles onto the substrate SUB.

FIG. 6 illustrates movement of the carrier CR when the second attractive force AF2 is less than the sum of the first attractive force AF1, the weight Wc of the carrier CR, and the weight Ws of the substrate SUB fixed to the carrier CR. Similar to the case illustrated in FIG. 5, this situation may frequently occur during the operation of the substrate transfer apparatus 10. It may arise when the second attractive force AF2 deviates from a balanced state with the sum of the first attractive force AF1, the weight Wc of the carrier CR, and the weight Ws of the substrate SUB fixed to the carrier CR.

As described above, the second attractive force AF2 refers to the force pulling the carrier CR toward the second magnet components MM2. Therefore, if the second attractive force AF2 is less than the sum of the first attractive force AF1, the weight Wc of the carrier CR, and the weight Ws of the substrate SUB fixed to the carrier CR, the carrier CR may be drawn toward the first chamber portion CH_1, where the first magnet components MM1 are installed. As such, as the carrier CR moves toward the first chamber portion CH_1, the roller components RM may gradually approach the second roller guide RG2 in the first concave portion CR_cp1, eventually making contact with the second roller guide RG2.

The force with which the roller components RM contact the second roller guide RG2 is determined by subtracting the second attractive force AF2 from the sum of the first attractive force AF1, the weight Ws of the substrate SUB, and the weight Wc of the carrier CR. Since the second attractive force AF2 is a significant magnetic force, the resulting contact force is much smaller than a frictional force that would otherwise be generated between the roller components RM and the second roller guide RG2 (i.e., the chamber CH) if the second roller guide RG2 were to fully support the weight Ws of the substrate SUB and the weight Wc of the carrier CR without the assistance of the second attractive force AF2. This means that, in the case of the substrate transfer apparatus 10 according to the embodiments, friction between the carrier CR and the roller components RM is significantly reduced compared to a system that does not utilize the first to third magnet components MM1 to MM3. As a result, even if foreign particles are generated during the transfer of the substrate SUB, the overall amount of such particles can be significantly minimized.

In addition, since the first concave portion CR_cp1 is formed on the surface of the carrier CR opposite to the surface of the carrier CR where the substrate SUB is fixed, any foreign particles generated due to friction between the carrier Cr and the roller components RM are unlikely to significantly escape from the first concave portion CR_cp1 and its surrounding area. This effectively prevents the introduction of foreign particles into the substrate SUB.

As described with reference to FIGS. 5 and 6, due to the configuration including the first concave portion CR_cp1 and the roller components RM, the substrate transfer apparatus 10 may reliably transfer the substrate SUB even if the second attractive force AF2 deviates from a state of balance with the sum of the first attractive force AF1, the weight Wc of the carrier CR, and the weight Ws of the substrate SUB fixed to the carrier CR. Furthermore, the configuration can prevent introduction of foreign particles into the substrate SUB, thereby mitigating defects in the display device.

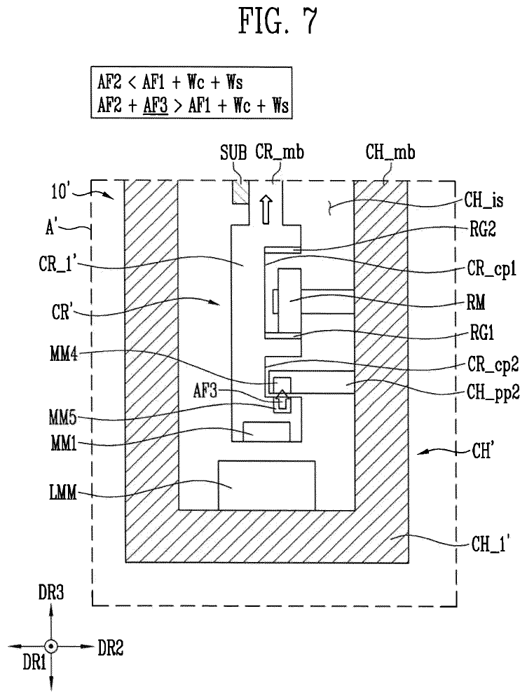

FIG. 7 is a view illustrating a modified embodiment of the substrate transfer apparatus illustrated in FIG. 6.

Referring to FIG. 7, a first carrier portion CR_1′ may further include a second concave portion CR_cp2 formed parallel to the first concave portion CP_cp1 with respect to the second direction DR2. Furthermore, the first chamber portion CH_1′ may further include a second protrusion CH_pp2 protruding toward the second concave portion CR_cp2.

The other components, except for the second concave portion CR_cp2 and the second protrusion CH_pp2, may have the same configuration as those indicated by the corresponding reference numerals in FIG. 6; therefore, redundant descriptions will be omitted. Furthermore, the second chamber portion CH_2 and the second carrier portion CR_2, which are not illustrated in FIG. 7, as well as the plurality of second and third magnet components MM2 and MM3, may have the same configuration as those indicated by the corresponding reference numerals in FIG. 3; therefore, redundant descriptions will also be omitted.

FIG. 7 illustrates movement of the carrier CR′ when the second attractive force AF2 is less than the sum of the first attractive force AF1, the weight Wc of the carrier CR′, and the weight Ws of the substrate SUB fixed to the carrier CR′, similar to FIG. 6.

A plurality of fourth magnet components MM4 may be installed in the second protrusion CH_pp2 illustrated in FIG. 7. A plurality of fifth magnet components MM5 may be installed in the first carrier portion CR_1′ facing the fourth magnet components MM4. A third attractive force AF3 may act between the plurality of fourth and fifth magnet components MM4 and MM5.

Since the second protrusion CH_pp2 where the fourth magnet components MM4 are installed is fixed in the first chamber portion CH_1′, the third attractive force AF3 refers to a force pulling the carrier CR′ toward the fourth magnet components MM4. Here, the sum of the second and third attractive forces AF2 and AF3 may be greater than the sum of the first attractive force AF1, the weight Wc of the carrier CR′, and the weight Ws of the substrate SUB.

In other words, the third attractive force AF3 acts as a supplementary force to the second attractive force AF2, allowing for adjustment so that the combined effect of the second and third attractive forces AF2 and AF3 exceeds the sum of the first attractive force AF1, the weight Wc of the carrier CR′, and the weight Ws of the substrate SUB. With the addition of the fourth and fifth magnet components MM4 and MM5 generating the third attractive force AF3, a force moving the carrier CR′ toward the second chamber portion CH_2 may still be applied even when the second attractive force AF2 alone is less than the sum of the first attractive force AF1, the weight Wc of the carrier CR′, and the weight Ws of the substrate SUB.

As described above, the second and third attractive forces AF2 and AF3 pull the carrier CR′ toward the second chamber portion CH_2 where the second magnet components MM2 are installed (refer to FIG. 3). Therefore, if the combined second and third attractive forces AF2 and AF3 exceed the sum of the first attractive force AF1, the weight Wc of the carrier CR′, and the weight Ws of the substrate SUB secured to the carrier CR′, the carrier CR′ will experience a force to drawing it closer to the second chamber portion CH_2. Consequently, as the carrier CR′ moves toward the second chamber portion CH_2, the roller components RM may gradually approach the first roller guide RG1 within the first concave portion CR_cp1, eventually making contact with the first roller guide RG1.

The force with which the roller components RM contact the first roller guide RG1 is determined by subtracting the sum of the first attractive force AF1, the weight Ws of the substrate SUB, and the weight Wc of the carrier CR′ from the second and third attractive forces AF2 and AF3. Since the second and third attractive forces AF2 and AF3 are considerable magnetic forces, the resulting contact force is significantly smaller than a frictional force that would otherwise be generated between the roller components RM and the first roller guide RG1 (i.e., the chamber CH) if the first roller guide RG1 fully supported the weight Ws of the substrate SUB and the weight Wc of the carrier CR′ without the assistance of the second and third attractive forces AF2 and AF3. This means that, in the substrate transfer apparatus 10′ according to the embodiments, friction between the carrier CR′ and the roller components RM is significantly reduced compared to a system that does not utilize the first to fifth magnet components MM1 to MM5. As a result, even if foreign particles are generated during the transfer of the substrate SUB, the overall amount of such particles can be significantly minimized.

In addition, since the first concave portion CR_cp1 is formed on the surface of the carrier CR′ opposite to the surface of the carrier CR′ where the substrate SUB is fixed, any foreign particles generated due to friction between the carrier CR′ and the roller components RM are unlikely to significantly escape from the first concave portion CR_cp1 and its surrounding area. This effectively prevents the introduction of foreign particles onto the substrate SUB.

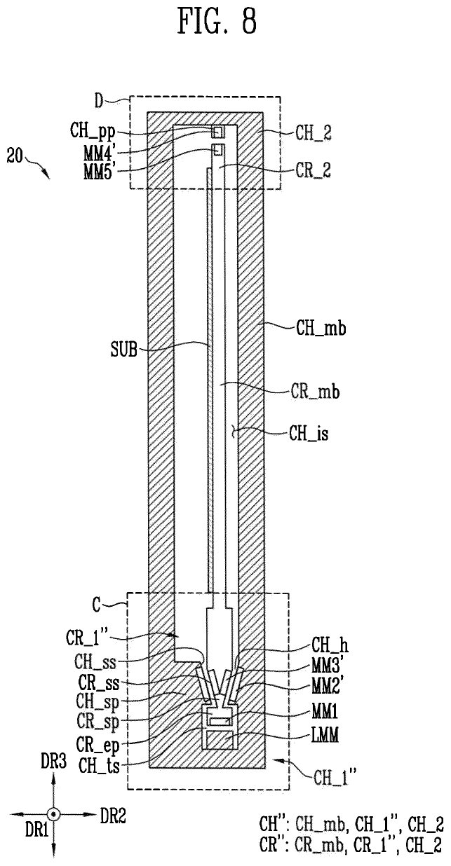

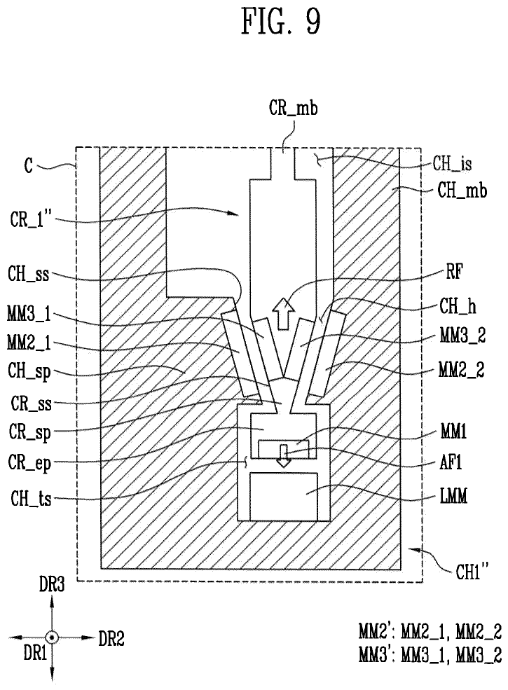

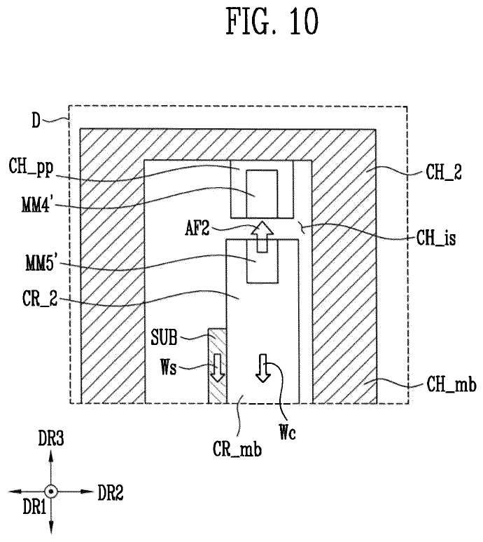

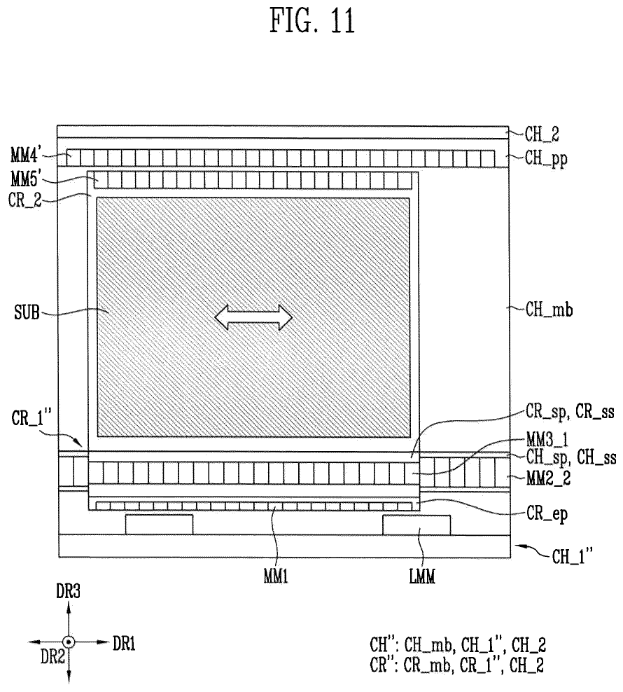

FIG. 8 is a view illustrating another embodiment of the substrate transfer apparatus illustrated in FIG. 1. FIG. 9 is a view illustrating an enlargement of portion C of FIG. 8. FIG. 10 is a view illustrating an enlargement of portion D of FIG. 8. FIG. 11 is a front view illustrating the substrate transfer apparatus 20 illustrated in FIG. 8.

Referring to FIGS. 8 to 11, the substrate transfer apparatus 20 may include a chamber CH″, a carrier CR″, a plurality of linear movable components LMM, a plurality of first magnet components MM1, a plurality of second magnet components MM2′, a plurality of third magnet components MM3′, a plurality of fourth magnet components MM4′, and a plurality of fifth magnet components MM5′.

The chamber CH″ may be a component that provides a space for performing a deposition process in a state enclosed from external conditions. A process of depositing a material that forms a light emitting element or circuit element on the substrate SUB introduced into the chamber CH″ may be performed in the chamber CH″. Although not illustrated in the drawings, a passage for introducing the substrate SUB into the chamber CH″ or removing the substrate SUB therefrom, and a door for opening and closing the passage may be provided on a side surface of the chamber CH″.

The chamber CH″ may include a main chamber body CH_mb, a first chamber portion CH_1″, and a second chamber portion CH_2.

The main chamber body CH_mb may be disposed to overlap, in each of the first and second directions DR1 and DR2, the substrate SUB introduced into the chamber CH″. Here, the first direction DR1 may refer to a direction in which the substrate SUB is transferred. The second direction DR2 may refer to a thickness direction of the substrate SUB.

The first chamber portion CH_1″ may refer to a portion of the chamber CH″ disposed on a first side of the chamber CH″ in the third direction DR3. The second magnet components MM2′ may be installed in the first chamber portion CH_1″ to face the carrier CR″ in the second direction DR2. In the embodiments, the first chamber portion CH_1″ may include a chamber hole CH_h, a chamber transfer space CH_ts, and a chamber slant portion CH_sp.

The chamber hole CH_h may be formed in the first chamber portion CH_1″, and may be open in a direction toward the second chamber portion CH_2 along the third direction DR3.

The chamber transfer space CH_ts may be an empty space provided in the chamber CH″ for communicating with the chamber hole CH_h. The linear movable components LMM may be installed in the chamber transfer space CH_ts. A carrier end portion CR_ep may be disposed in the chamber transfer space CH_ts.

The chamber slant portion CH_sp may be a portion of the first chamber portion CH_1″. The chamber hole CH_h, which exposes the chamber transfer space CH_ts to the outside, and a chamber slant surface CH_ss, which face the carrier slant portion CR_sp (described below), may be formed in the chamber slant portion CH_sp. In other words, the chamber slant surface CH_ss may be an inner surface of the chamber slant portion CH_sp that encloses the chamber hole CH_h, and extends in the first direction DR1 (refer to FIG. 11). The second magnet components MM2′ may be installed in the chamber slant surface CH_ss. Details of the second magnet components MM2′ will be described below.

The second chamber portion CH_2 may refer to another portion of the chamber CH″ disposed on a second side of the chamber CH″ in the third direction DR3. The fourth magnet components MM4′ may be installed in the second chamber portion CH_2. A protrusion CH_pp where the fourth magnet components MM4′ are disposed may be formed in the second chamber portion CH_2. Details of the fourth magnet components MM4′ and the protrusion CH_pp will be described below.

The carrier CR″ may be a component configured to transfer the substrate SUB in the first direction DR1, and may be placed vertically in the third direction DR3 while securing the substrate SUB thereon, thus allowing for introduction into or removal from the chamber CH″. The substrate SUB may be fixed on the carrier CR″ by various methods. For example, the carrier CR″ may use a device such as a clamper or an electrostatic chuck to fix the substrate SUB on a surface of the carrier CR″.

The carrier CR″ may include a main carrier body CR_mb, a first carrier portion CR_1″, and a second carrier portion CR_2.

The main carrier body CR_mb may be disposed to overlap the main chamber body CH_mb in each of the first and second directions DR1 and DR2. Since it has been described above that the main chamber body CH_mb may overlap the substrate SUB in each of the first and second directions DR1 and DR2, this implies that the main carrier body CR_mb may also overlap the substrate SUB in each of the first and second directions DR1 and DR2.

The first carrier portion CR_1″ may refer to a portion of the carrier CR″ disposed on a first side of the carrier CR″ in the third direction DR3. The first carrier portion CR_1″ may be adjacent to the first chamber portion CH_1″. In other words, the first chamber portion CH_1″ and the first carrier portion CR_1″ may be disposed adjacent to each other in one area of the substrate transfer apparatus 20.

The first magnet components MM1 may be installed in the first carrier portion CR_1″ to face the linear movable components LMM in the first direction DR1. In the embodiments, the first carrier portion CR_1″ may include the carrier end portion CR_ep and the carrier slant portion CR_sp.

The carrier end portion CR_ep may correspond to a portion of the carrier CR″ received in the chamber transfer space CH_ts of the first chamber portion CH_1″. The first magnet components MM1 may be installed in the carrier end portion CR_ep.

The carrier slant portion CR_sp may correspond to a portion of the carrier CR″ disposed between the main carrier body CR_mb and the carrier end portion CR_ep. The third magnet components MM3′ may be installed in the carrier slant portion CR_sp. Details of the third magnet components MM3′ will be described below.

The second carrier portion CR_2 may refer to another portion of the carrier CR″ disposed on a second side of the carrier CR″ in the third direction DR3. The fifth magnet components MM5′ may be installed in the second carrier portion CR_2. Details of the fifth magnet components MM5′ will be described below.

The linear movable components LMM may be installed in the chamber CH″ to provide a driving force for moving the carrier CR″ in the first direction DR1. Specifically, the linear movable components LMM may be installed in the first chamber portion CH_1″ and arranged with spacing between them in the first direction DR1, which is the direction in which the substrate SUB is transferred. Additionally, they may be disposed to face the first carrier portion CR_1″ in the third direction DR3.

The linear movable components LMM may use a magnetic force to transfer the carrier CR″ in the first direction DR1. For example, each of the linear movable components LMM may include an armature coil. The linear movable components LMM may be disposed to face the first magnet components MM1 (described below) in the third direction. By applying current to each of the linear movable components LMM, a driving force a driving force may be generated to transfer the carrier CR″ in the first direction DR1.

The first magnet components MM1 may be configured as permanent magnets with specific magnetic forces, and may be installed in the carrier CR″ to face the linear movable components LMM in the third direction DR3. In the embodiments, the first magnet components MM1 may be installed in the carrier end portion CR_ep of the first carrier portion CR_1″, which is adjacent to the first chamber portion CH_1″ in the third direction DR3. However, their placement is not limited to this configuration. For example, the first magnet components MM1 may be embedded in the carrier end portion CR_ep.

As illustrated in FIG. 9, a first attractive force AF1 may act between the linear movable components LMM and the first magnet components MM1. Here, the first attractive force AF1 may refer to an electrostatic force that causes the linear movable components LMM and the first magnet components MM1 to attract each other in the third direction DR3. In the embodiments, the linear movable components LMM are installed in the fixed chamber CH″, while the first magnet components MM1 are installed in the carrier CR″, which has a certain degree of freedom in the third direction. Consequently, the carrier CR″ may experience a force that draws the first carrier portion CR_1″ toward the first chamber portion CH_1″ due to the first attractive force AF1.

The second magnet components MM2′ may be configured as permanent magnets with specific magnetic forces, similar to the first magnet components MM1, and may be installed in the first chamber portion CH_1″. These components may be inclined at a certain angle with respect to the third direction DR3. In the embodiments, the second magnet components MM2′ may include a plurality of 2_1-th magnet components MM2_1 and a plurality of 2_2-th magnet components MM2_2, which are symmetrically positioned relative to the third direction DR3. The 2_1-th and 2_2-th magnet components MM2_1 and MM2_2 may be installed in the chamber slant surface CH_ss, which is formed in the chamber slant portion CH_sp of the first chamber portion CH_1″.

The third magnet components MM3′ may be configured as permanent magnets with specific magnetic forces, similar to the first and second magnet components MM1 and MM2′, and may be installed in the first carrier portion CR_1″. These components may be inclined at a certain angle with respect to the third direction DR3. In the embodiments, the third magnet components MM3′ may include a plurality of 3_1-th magnet components MM3_1 and a plurality of 3_2-th magnet components MM3_2, which are symmetrically positioned relative to the third direction DR3. The 3_1-th and 3_2-th magnet components MM3_1 and MM3_2 may be installed in the carrier slant surface CR_ss, which is formed in the carrier slant portion CR_sp of the first carrier portion CR_1″.

The chamber slant surface CH_ss of the chamber slant portion CH_sp and the carrier slant surface CR_ss of the carrier slant portion CR_sp may be parallel to each other. Due to this structure, the second magnet components MM2′ installed in the chamber slant surface CH_ss and the third magnet components MM3′ installed in the carrier slat surface CR_ss may also be arranged in parallel.

As illustrated in FIG. 9, a repulsive force RF may act between the second magnet components MM2′ and the third magnet components MM3′. Here, the repulsive force RF may refer to a magnetic force that causes the second magnet components MM2′ and the third magnet components MM3′ to repel each other in the third direction DR3. In the embodiments, the second magnet components MM2′ are installed in the fixed chamber CH″, while the third magnet components MM3′ are installed in the carrier CR″, which has a certain degree of freedom in the third direction DR3. As a result, the carrier CR″ may experience a force that moves the first carrier portion CR_1″ away from the first chamber portion CH_1″ due to the repulsive force RF.

A repulsive force generated between the plurality of 2_1-th and 3_1-th magnet components MM2_1 and MM3_1 may be divided into components in the second and third directions DR2 and DR3, respectively. A repulsive force generated between the plurality of 2_2-th and 3_2-th magnet components MM2_2 and MM3_2 may also be divided into components in the second and third directions DR2 and DR3, respectively. Specifically, the repulsive force exerted by the 2_1-th magnet components MM2_1 on the 3_1-th magnet components MM3_1 in the second direction DR2 and the repulsive force exerted by the 2_2-th magnet components MM2_2 on the 3_2-th magnet components MM3_2 in the second direction DR2 may cancel each other out. Therefore, the carrier CR″ is not moved by a net repulsive force in the second direction DR2 generated between the plurality of second and third magnet components MM2′ and MM3′. On the other hand, the repulsive force exerted by the 2_1-th magnet components MM2_1 on the 3_1-th magnet components MM3_1 in the third direction DR3 and the repulsive force exerted by the 2_2-th magnet components MM2_2 on the 3_2-th magnet components MM3_2 in the third direction DR3 may act in the same direction. Therefore, a magnetic force in the third direction DR3 generated between the plurality of second and third magnet components MM2′ and MM3′ may be concentrated into a single repulsive force RF.

The fourth magnet components MM4′ may be configured as permanent magnets with specific magnetic forces, similar to the first to third magnet components MM1, MM2′, and MM3′. They may be installed in a portion of the chamber CH″ on a side opposite to the first magnet components MM1 in the third direction DR3. In the embodiments, the fourth magnet components MM4′ may be installed at the end of the protrusion CH_pp, which extends from the second chamber portion CH_2 toward the second carrier portion CR_2 in the third direction DR3. However, their placement is not limited to this configuration. For example, the fourth magnet components MM4′ may be embedded in the end of the protrusion CH_pp.

In some embodiments, the protrusion CH_pp may be omitted. In other embodiments, the fourth magnet components MM4′ may be installed on a surface of the second chamber portion CH_2 that is adjacent to the second carrier portion CR_2. However, their placement is not limited to this configuration. For example, the fourth magnet components MM4′ may be embedded in a surface of the second chamber portion CH_2 that faces the second carrier portion CR_2 in the third direction DR3.

The fifth magnet components MM5′ may be configured as permanent magnets with specific magnetic forces, similar to the first to fourth magnet components MM1, MM2′, MM3′, and MM4′. They may be installed in the carrier CR″ to face the fourth magnet components MM4′ in the third direction DR3. In the embodiments, the fifth magnet components MM5′ may be installed in a surface positioned at an end of the second carrier portion CR_2, adjacent to the second chamber portion CH_2 in the third direction DR3. However, their placement is not limited to this configuration. For example, the fifth magnet components MM5′ may be embedded in the end of the second carrier portion CR_2.

As illustrated in FIG. 10, a second attractive force AF2 may act between the fourth magnet components MM4′ and the fifth magnet components MM5′. Here, the second attractive force AF2 may refer to a magnetic force that causes the fourth magnet components MM4′ and the fifth magnet components MM5′ to attract each other in the third direction DR3. In the embodiments, the fourth magnet components MM4′ are installed in the fixed chamber CH″, while the fifth magnet components MM5′ are installed in the carrier CR″, which has a certain degree of freedom in the third direction DR3. Consequently, the carrier CR″ may experience a force that moves the second carrier portion CR_2 toward the second chamber portion CH_2 due to the second attractive force AF2.

Referring collectively to FIGS. 9 and 10, the second attractive force AF2 acts in a direction opposite to the force pulling the carrier CR″ toward the first chamber portion CH_1′ due to the first attractive force AF1, the weight Ws of the substrate SUB, or the weight Wc of the carrier CR″. In the embodiments, when the sum of the second attractive force AF2 and the repulsive force RF balances the combined effect of the first attractive force AF1, the weight Ws of the substrate SUB, and the weight Wc of the carrier CR″, the carrier CR″ may be maintained in a non-contact state with the chamber CH″, achieving magnetic levitation, as illustrated in FIGS. 8 and 9. In other words, the carrier CR″ may be transferred while suspend, with the linear movable components LMM and the first magnet components MM1 remaining spaced apart due to the magnetic forces acting between the plurality of second and third magnet components MM2′ and MM3′ and between the plurality of fourth and fifth magnet components MM4′ and MM5′.

If the repulsive force RF acting between the plurality of second and third magnet components MM2′ and MM3′ and the second attractive force AF2 acting between the plurality of fourth and fifth magnet components MM4′ and MM5′ are not utilized, the carrier CR″ will inevitably come into contact with the driving system installed in the chamber CH″ during movement. In this case, fine particles generated by friction between the carrier CR″ and the driving system of the chamber CH″ may infiltrate the substrate SUB. Since multiple layers of thin films forming the light emitting element and the circuit element of the display device are deposited on the substrate SUB, the introduction of foreign particles into these thin films may result in defects in the display device.

However, in the case of the substrate transfer apparatus 20 according to the above-described embodiments, the sum of the second attractive force AF2 and the repulsive force RF may balance to combined effect of the first attractive force AF1, the weight Ws of the substrate SUB, and the weight Wc of the carrier CR″. Accordingly, the carrier CR″ can be transferred without contact with other components, preventing friction between the carrier CR″ and the driving system of the chamber CH″ during the substrate SUB transfer process. This effectively eliminates the generation of foreign particles, thereby reducing the risk of defects in the display device.

According to a substrate transfer apparatus described above, friction between a carrier and a chamber (driving system) during substrate transfer can be reduced, thereby mitigating defects in a display device caused by foreign particles and improving the durability of the substrate transfer apparatus. For example, by installing magnet components in both the chamber and the carrier to generate a magnetic force enabling magnetic levitation, the substrate can be transferred while maintaining a gap between the chamber and the carrier. This prevents the occurrence of foreign particles and reduces abrasion of the chamber.

Furthermore, in the substrate transfer apparatus in accordance with the embodiments, the transfer reliability may be improved. For example, since a plurality of roller components are disposed within a concave portion formed in the carrier, the substrate may be reliably transferred while maintaining a stable orientation, even if the carrier is not in the magnetic levitation state.

However, effects of this disclosure are not limited to those described above, and various modifications can be made without departing from the spirit and scope of this disclosure.

Although specific embodiments and application examples have been described, other embodiments and modifications may be derived from the disclosure provided. Accordingly, this disclosure is not limited to the foregoing embodiments but extends to the appended claims, along with various modifications and equivalents.

What is claimed is:

1. A substrate transfer apparatus, comprising:
a chamber;
a carrier including a first concave portion facing the chamber and extending in a first direction, wherein the carrier is configured to be positioned vertically in a second direction intersecting with the first direction while securing a substrate thereon, and introduced into or removed from the chamber in the first direction;
a plurality of roller components installed in the chamber and positioned in the first concave portion;
a plurality of linear movable components installed in the chamber and configured to generate a driving force for transferring the carrier in the first direction;
a plurality of first magnet components installed in the carrier and positioned to face the plurality of linear movable components in the second direction;
a plurality of second magnet components installed in the chamber on a side opposite to the plurality of first magnet components in the second direction; and
a plurality of third magnet components installed in the carrier and positioned to face the plurality of second magnet components,
wherein the carrier is transferred while maintaining a gap between the plurality of linear movable components and the plurality of first magnet components, with the transfer being facilitated by a magnetic force acting between the plurality of second magnet components and the plurality of third magnet components.

2. The substrate transfer apparatus according to claim 1, wherein the first direction is a horizontal direction, and the second direction is a vertical direction.

3. The substrate transfer apparatus according to claim 1,
wherein the chamber includes a first chamber portion, and a second chamber portion positioned on a side opposite to the first chamber portion with respect to the second direction, and
wherein the carrier includes a first carrier portion adjacent to the first chamber portion, and a second carrier portion adjacent to the second chamber portion.

4. The substrate transfer apparatus according to claim 3,
wherein the plurality of roller components are arranged in the first chamber portion in the first direction, and
wherein the first concave portion is formed in the first carrier portion in the first direction.

5. The substrate transfer apparatus according to claim 3,
wherein the plurality of linear movable components are installed in the first chamber portion, and
wherein the first magnet components are installed in the first carrier portion.

6. The substrate transfer apparatus according to claim 3,
wherein the plurality of second magnet components are installed in the second chamber portion, and
wherein the third magnet components are installed in the second carrier portion.

7. The substrate transfer apparatus according to claim 3,
wherein the chamber includes a first protrusion protruding from the second chamber portion in the second direction, and
wherein the plurality of second magnet components are installed in the first protrusion.

8. The substrate transfer apparatus according to claim 1,
wherein a first attractive force acts between the plurality of linear movable components and the first magnet components, and
wherein a second attractive force acts between the plurality of second magnet components and the plurality of third magnet components.

9. The substrate transfer apparatus according to claim 8, wherein the first concave portion comprises:
a first roller guide disposed adjacent to a first side of the chamber; and
a second roller guide disposed adjacent to a second side of the chamber.

10. The substrate transfer apparatus according to claim 9, wherein the first roller guide and the second roller guide are integrally formed with the carrier.

11. The substrate transfer apparatus according to claim 9, wherein the first roller guide and the second roller guide include a material different from a material of the carrier.

12. The substrate transfer apparatus according to claim 9,
wherein when the second attractive force is greater than a sum of the first attractive force, a weight of the carrier, and a weight of the substrate secured to the carrier,
the carrier moves toward the plurality of second magnet components, and
the plurality of roller components come into contact with the first roller guide.

13. The substrate transfer apparatus according to claim 9,
wherein when the second attractive force is less than a sum of the first attractive force, a weight of the carrier, and a weight of the substrate secured to the carrier,
the carrier moves toward the plurality of first magnet components, and
the plurality of roller components come into contact with the second roller guide.

14. The substrate transfer apparatus according to claim 9,
wherein the carrier further includes a second concave portion formed parallel to the first concave portion along the second direction, and
wherein the chamber includes a second protrusion protruding toward the second concave portion.

15. The substrate transfer apparatus according to claim 14, further comprising:
a plurality of fourth magnet components installed in the second protrusion; and
a plurality of fifth magnet components installed in the carrier and positioned to face the plurality of fourth magnet components,
wherein the carrier moves toward the plurality of second magnet components due to a third attractive force acting between the plurality of fourth magnet components and the plurality of fifth magnet components.

16. The substrate transfer apparatus according to claim 15,
wherein when a sum of the second attractive force and the third attractive force is greater than a sum of the first attractive force, a weight of the carrier, and a weight of the substrate secured to the carrier,
the carrier moves toward the plurality of second magnet components, and
the plurality of roller components come into contact with the first roller guide.

17. A substrate transfer apparatus, comprising:
a chamber;
a carrier configured to be placed in a first direction while securing a substrate thereon, and introduced into or removed from the chamber;
a plurality of linear movable components installed in a first chamber portion of the chamber, and configured to generate a driving force for transferring the carrier in a second direction intersecting with the first direction;
a plurality of first magnet components installed in a first carrier portion of the carrier and positioned to face the plurality of linear movable components in the first direction;
a plurality of second magnet components installed in the first chamber portion and inclined at a first angle with respect to the first direction;
a plurality of third magnet components installed in the first carrier portion and positioned to face the plurality of second magnet components while being inclined at a second angle with respect to the first direction;
a plurality of fourth magnet components installed in a second chamber portion positioned on a side opposite to the first chamber portion with respect to the first direction; and
a plurality of fifth magnet components installed in a second carrier portion adjacent to the second chamber portion and positioned to face the plurality of fourth magnet components,
wherein the carrier is transferred while maintaining a gap between the plurality of linear movable components and the plurality of first magnet components are spaced apart, with the transfer being facilitated by a magnetic force acting between the plurality of second magnet components and the plurality of third magnet components.

18. The substrate transfer apparatus according to claim 17,
wherein the plurality of second magnet components comprise a plurality of 2_1-th magnet components and a plurality of 2_2-th magnet components, which are symmetrically arranged with respect to the first direction,
wherein the plurality of third magnet components comprise a plurality of 3_1-th magnet components and a plurality of 3_2-th magnet components, which are symmetrically arranged with respect to the first direction,
wherein the plurality of 2_1-th magnet components and the plurality of 3_1-th magnet components face each other,
wherein the plurality of 2_2-th magnet components and the plurality of 3_2-th magnet components face each other,
wherein a first repulsive force acts between the plurality of 2_1-th magnet components and the plurality of 3_1-th magnet components, and
wherein a second repulsive force acts between the plurality of 2_2-th magnet components and the plurality of 3_2-th magnet components.

19. The substrate transfer apparatus according to claim 17,
wherein the first carrier portion comprises:
a carrier end portion where the plurality of first magnet components are installed; and
a carrier slant portion where the plurality of third magnet components are installed,
wherein the first chamber portion comprises:
a chamber transfer space positioned at the carrier end portion; and
a chamber slant portion facing the carrier slant portion, with a chamber hole formed in the chamber slant portion to expose the chamber transfer space,
wherein a chamber slant surface of the chamber slant portion and a carrier slant surface of the carrier slant portion are parallel to each other,
wherein the plurality of second magnet components are installed in the chamber slant surface, and
wherein the plurality of third magnet components are installed in the carrier slant surface.

20. The substrate transfer apparatus according to claim 17,
wherein a first attractive force acts between the plurality of linear movable components and the plurality of first magnet components, and
wherein a repulsive force acts between the plurality of second magnet components and the plurality of third magnet components, and
wherein a second attractive force acts between the plurality of fourth magnet components and the plurality of fifth magnet components, and
wherein a sum of the first attractive force, a weight of the carrier, and a weight of the substrate secured to the carrier is substantially equal to a sum of the second attractive force and the repulsive force.
